(19) United States
(12) Patent Application Publication
(10) Pub. No.: US 2026/0307916 A1
(43) Pub. Date: Oct. 8, 2026

(54) CARRYING METHOD AND DEVICE FOR CLEANING FOUP

(71) Applicant: ASIA NEO TECH INDUSTRIAL CO., LTD., TAOYUAN CITY (TW)

(72) Inventors: PU-CHANG YEH, TAOYUAN CITY (TW); CHING-YUAN LIN, TAOYUAN CITY (TW)

(21) Appl. No.: 19/271,487

(22) Filed: Jul. 16, 2025

(30) Foreign Application Priority Data
Apr. 8, 2025 (TW) 114113248

(51) Int. Cl. B65G 47/90; H10P 72/30; B08B 9/08

(52) U.S. Cl. CPC B65G 47/90; H10P 72/3218; B08B 9/0826; B08B 2209/08

(57) ABSTRACT

A carrying method and device for cleaning the FOUP is disclosed. The method constructs a one-time transportation path for a gripper of the robot, comprising: simultaneously carrying the FOUP from a load port to an unlocking station for unlocking the FOUP to separate the shell from the door, and simultaneously transporting the shell and the door to a plurality of cleaning stations for cleaning, and then transporting the cleaned shell and door back to the unlocking station, where they are locked together to present a cleaned FOUP. Thus, the path of transportation is simplified and the man-hour for handling the FOUPs is reduced.

### FIELD OF THE INVENTION

The present invention relates generally to a FOUP carrying technique, and more particularly to a carrying method and device for cleaning FOUP.

### DESCRIPTION OF RELATED ART

A Front-Opening Unified Pod (FOUP) is composed of a hollow shell locked with a door. In semiconductor manufacturing processes, FOUPs are commonly used to house wafers and are filled with specific gases. Subsequently, the FOUPs are transported by Overhead Hoist Transport (OHT) systems to various workstations for semiconductor wafer processing. Furthermore, FOUPs are gradually utilized to house substrates, panels, or other precision components. This enables their transportation via OHT systems to respective processing stations for necessary manufacturing steps.

In the semiconductor manufacturing process for example, the basic structure and specifications of FOUPs have been standardized and restricted. Please refer to FIG. 1, which illustrates the integrated state of the shell 11 and the door 12 of a FOUP 10 connected via a locking mechanism. Specifically, the shell 11 is roughly a hollow quadrilateral body with an opening 13, and the door 12 covers the opening 13 after being locked. A flange 15 (commonly referred to as a "mushroom head") is formed on one side wall of the shell 11, specifically designed for external equipment (e.g., overhead cranes) to clamp and transport the FOUP. It is noted that the flange 15 possesses sufficient strength to withstand the forces exerted during clamping and transportation.

Additionally, the surface of the door 12 is provided with a pair of key holes 14, which allows a pair of keys to be inserted to unlock the door 12 on the shell 11, thereby exposing the opening 13 of the shell 11 to put in the aforementioned process component or take out the process component from within the shell 11. It is to be noted that, in the state where the shell 11 and door 12 are locked and combined as a single unit, the door 12 (including the key hole 14) and the flange 15 are respectively positioned on different end walls of the shell 11. More specifically, the door 12 (including the key hole 14) and the flange 15 are positioned on different end walls of the shell 11 that adjoin at approximately a 90-degree angle.

The aforementioned FOUP requires cleaning after being used for a certain period to remove harmful substances accumulated or remaining on the shell and the door. These harmful substances include dust particles, volatile organic compounds (VOC), sulfur dioxide (SO2), Amines, Acids, Ammonia (NH3) etc. The cleaning procedure ensures good quality of the process components during manufacturing. Therefore, in processing area stations where FOUPs are used to transport process components for production, often a special cleaning area station designed for FOUP cleaning is provided to maintain cleanliness of the FOUPs.

The cleaning area station typically includes at least one load port for converting the FOUPs transported by overhead cranes into or out of the cleaning area station. More specifically, overhead cranes transfer FOUPs to be cleaned into the load port, and the cleaning area station is equipped with an automatic machine, usually constructed from multi-axis robotic arms that can move flexibly. This automatic machine is attached with a gripper 16 (also known as a fixture, as shown in FIG. 1), which is used to automatically collect, transport, and place each FOUP 10 into the cleaning station for cleaning procedures. After cleaning, the automatic machine transports the cleaned FOUP 10 back to the load port for retrieval by the overhead crane.

Prior to cleaning, the door 12 on the shell 11 of the FOUP must be unlocked to allow separate cleaning of the shell 11 and door 12. In existing FOUP cleaning techniques, an unlocking station is established in the cleaning area station. After the gripper 16 of the automatic machine collects the FOUP from the load port, it firstly transfers the FOUP to the unlocking station, where keys are provided to unlock the door 12 on the shell 11. Once unlocked, the door 12 remains at the unlocking station, while the shell 11 is retained on the gripper 16. The automatic machine then transports the shell 11 to a cleaning chamber in the cleaning area station. Subsequently, the automatic machine returns to the unlocking station to collect the door 12 and transports it to the cleaning chamber for cleaning. The shell 11 and door 12 may undergo cleaning in the same or different chambers.

However, in the prior art, after unlocking the FOUP, the gripper 16 must repeatedly transport the shell 11 and door 12 to and from the cleaning chamber, leading to increased transportation time and reduced operational efficiency of the cleaning area station.

To address this issue, a more advanced patent (CN102804332B) proposes a technique to reduce the operational time of the gripper 16 to transport FOUPs in the cleaning area station. Specifically, the patent discloses a gripper 16 driven by a multi-axis robotic arm, with a pair of clamps 162 configured on one end face 161, and an unlocking mechanism 163 integrated into the end face 161. This unlocking mechanism 163 incorporates the aforementioned keys to unlock the door 12.

The multi-axis robotic arm rotates the gripper 16 shown in FIG. 1 by 180 degrees, allowing the clamps 162 on the end face 161 to grip the two relative edges A and B around the shell 11 for transporting the entire FOUP 10 (as shown in FIG. 1). During transportation or before releasing the FOUP 10, the unlocking mechanism 163 on the end face 161 inserts the key into the key hole 14 of the door 12 to unlock it. Simultaneously, the clamps 162 on the end face 161 can grip the unlocked door 12, enabling transportation and sequential placement of the shell 11 and door 12 into designated cleaning positions. Thus, by using a single gripper 16, this patent eliminates the need for a dedicated unlocking station in the cleaning area station and resolves the problem of time consumption due to separated transportation of the shell 11 and door 12 into and out of the cleaning chamber.

However, since the unlocking mechanism 163 is mounted on the gripper 16, the end face 161 of the gripper 16 must cover the door 12 when unlocking the door, so as to enable the pair of clamps 162 to grip the two relative edges A and B around the shell 11 (as shown in FIG. 1). When the end face 161 covers the door 12, the key of the unlocking mechanism 163 can be easily inserted into the key hole 14 of the door 12.

However, the shell 11 is significantly heavier than the door 12, and the combined weight of the locked FOUP 10 after the shell 11 is locked with the door 12 is much greater than that of the door 12 alone. Moreover, edges A and B around the shell 11 are not standardized points for gripping by external equipment. In other words, this patent does not abide by the standard use of FOUPs, where the flange 15 is the designated gripping point. The approach of this patent may cause deformation of or damage to the shell 11 and may reduce the durability of the FOUPs. Therefore, improvement is needed.

### SUMMARY OF THE INVENTION

The technical problem to be overcome in this invention is: Due to the relatively heavier weight of the entire FOUP and its shell after unlocking and separation compared to the door, during the handling and unlocking of the FOUP for cleaning purposes, it is necessary to avoid the gripper clamping and handling the parts of the FOUP and its separated shell that are not designed for application of external forces. Specifically, since the door is lighter than the entire FOUP and the shell, and the door is configured with a flange, the gripper can clamp the peripheral edges of the door after unlocking.

Additionally, this invention also aims to simplify the transportation path for the gripper to handle the FOUP as well as the shell and door after unlocking and separation, thereby improving the transportation efficiency.

To address these issues, the invention provides a carrying method and device for cleaning FOUPs. The configuration of an independent unlocking station in the cleaning area station is maintained. The method utilizes the flange on the FOUP structure designed for clamping by the overhead crane as the clamping position for the gripper, so as to avoid deformation or damage to the FOUP.

In one preferred embodiment, the carrying method provided by the present invention is used for transportation of the FOUP for cleaning. Before cleaning, the FOUP includes a shell and a door locked on the shell. The FOUP and the shell are relatively heavier than the door. The carrying method involves constructing a one-time transportation path for the gripper to transport, disassemble, and assemble the FOUP between a load port, an unlocking station, and a cleaning station. The two end faces of the gripper are equipped with a first clamper and a second clamper. The one-time transportation path sequentially includes: (1) The first clamper clamps the shell at the load port, transports the FOUP to the unlocking station for unlocking the door on the shell, and lifts the shell while leaving the unlocked door at the unlocking station. (2) The second clamper clamps the unlocked door at the unlocking station, thus simultaneously transporting the shell and the door to the cleaning station for separate placement. (3) The first clamper clamps the shell at the cleaning station, and the second clamper clamps the door at the cleaning station, thus simultaneously transporting them to the unlocking station to assemble them to present the cleaned FOUP. (4) The first clamper clamps the shell at the unlocking station and transports the cleaned FOUP back to the load port. Specifically, one side of the shell is formed with a flange. When the gripper transports the FOUP and the shell, the flange provides a clamping position for the first clamper. When the gripper transports the door, the door is clamped by the second clamper. Through reciprocating rotation at a specific angle, the gripper allows the first clamper to clamp the flange, and allows the second clamper to clamp the door.

In another preferred embodiment, the carrying method provided by the present invention is used for transportation of the FOUP for cleaning. Before cleaning, the FOUP includes a shell and a door locked on the shell. The FOUP and the shell are relatively heavier than the door. The carrying device includes: an automatic machine, a first clamper and a second clamper. The automatic machine is connected to a gripper and located in a cleaning area station. Around the automatic machine in the cleaning area station, at least one load port, at least one unlocking station, and a plurality of cleaning stations are respectively deployed. The first clamper is configured on one end face of the gripper and is used to clamp and release a flange on the shell at the load port, the unlocking station, and the cleaning station. The second clamper is configured on the other end face of the gripper and is used to clamp and release the door at the load port, the unlocking station, and the cleaning station. Through reciprocating rotation at a specific angle, the gripper allows the first clamper to clamp the flange, and allows the second clamper to clamp the door.

In detailed implementation, the specific angle is 180 degrees. Furthermore, the two end faces of the gripper are parallel and correspond to each other. Additionally, the two side edges of the door are used for clamping by the second clamper.

The technical focus and efficacy of this invention are as follows: Through reciprocating rotation of the gripper at a specific angle of 180 degrees, the gripper can simultaneously clamp the door, the shell, or the entire FOUP at the load port, the unlocking station, and the cleaning station without altering the departure path, thereby simplifying the transportation path and reducing the handling time. Moreover, in this invention, the gripper clamps on the position of the flange. This fully complies with the standard for operating FOUPs and can avoid deformation of the FOUP or damage during prolonged use.

Further benefits and advantages of the present invention will become apparent after a careful reading of the detailed description with appropriate reference to the accompanying drawings.

### BRIEF DESCRIPTION OF THE DRAWINGS

FIG. 1 is a perspective view of a prior-art FOUP and a prior-art gripper, revealing that the FOUP is formed by locking a door on a shell, and the position where the gripper clamps the shell of the FOUP.

FIG. 2 is a top view layout diagram of the present invention implemented in a cleaning area station, revealing that a gripper and a plurality of cleaning stations are arranged in the cleaning area station.

FIG. 3 is a perspective view of the gripper shown in FIG. 2 from a first angle, revealing that one end face of the gripper is provided with a clamper capable of clamping the flange on the shell.

FIG. 4 is a perspective view of the gripper shown in FIG. 2 from a second angle, revealing that the other end face of the gripper is provided with a clamper capable of clamping the opposite end edges of the door.

FIG. 5 is a perspective view of the gripper shown in FIG. 3 and FIG. 4 clamping the shell and the door, revealing that the gripper can be turned for 180 degrees to clamp and place the shell and the door from different end faces.

FIG. 6 is a transportation path diagram of the present invention, revealing the transportation steps and processes of the gripper shown in FIG. 2 operating in the cleaning area station.

FIG. 7 is an auxiliary explanatory diagram of FIG. 6, illustrating the continuous action states of the gripper from (a) to (i) in FIG. 7.

### DETAILED DESCRIPTION OF THE INVENTION

Please refer to FIG. 2 first. The FOUP carrying method and device of the present invention are implemented in a cleaning area station 20. An automatic machine 30 is configured in the cleaning area station 20. The automatic machine 30 can be composed of a multi-axis robotic arm and is attached with a gripper 40 (also known as a fixture).

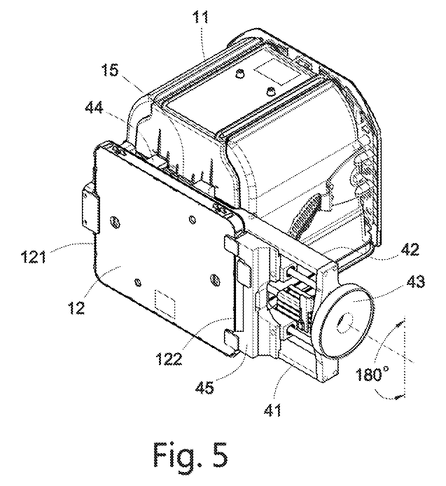

Around the automatic machine 30 in the cleaning area station 20, at least one load port 21, at least one unlocking station 22 and a plurality of cleaning stations 23 are respectively deployed. This enables the automatic machine 30 to drive the gripper 40 to the load port 21 in a multi-axis transmission manner to clamp and place the FOUP 10, and transport the FOUP 10 to the unlocking station 22 to unlock it and divide it into the shell 11 and the door 12, as shown in FIG. 5. Then, it can simultaneously transport the shell 11 and the door 12 to a plurality of cleaning stations 23 for cleaning.

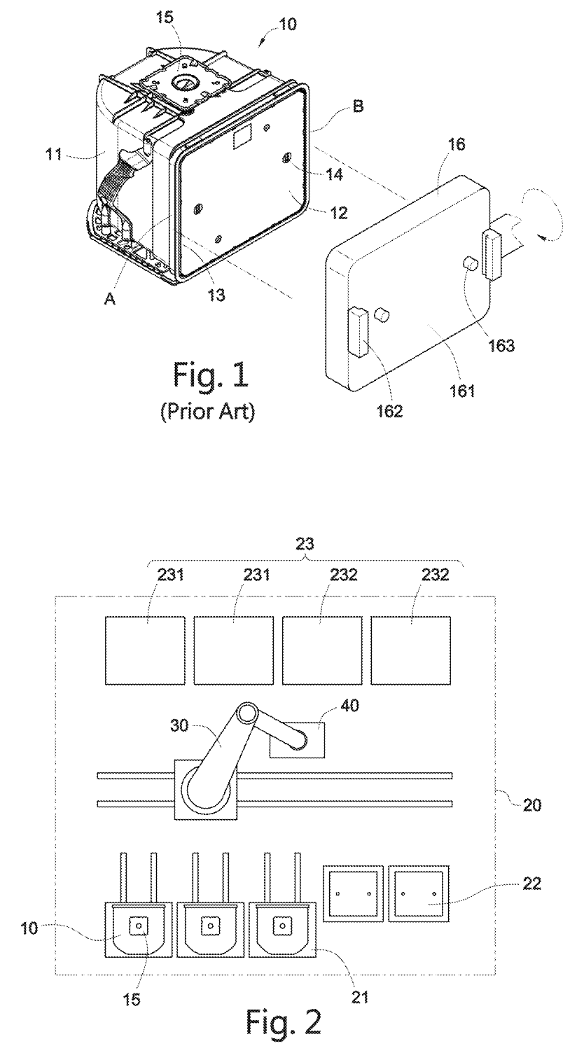

Further, the load port 21 is used to transfer the FOUP 10 carried by an overhead crane (not shown in the figure) into and out of the cleaning area station 20. The unlocking station 22 is used to unlock the door 12 on the shell 11 of the FOUP 10 (as shown in FIG. 1), and the unlocking station 22 can also lock the door 12 with the shell 11 to form the FOUP 10 after the door 12 is placed. The plurality of cleaning stations 23 may include at least one cleaning machine 231 and at least one vacuum drier 232. Among them:

Each of the cleaning machines 231 is used to house the unlocked shell 11 and door 12. Alternatively, the unlocked shell 11 and door 12 can be respectively placed in different cleaning machines 231 for wet cleaning of the shell 11 and the door 12. In known practices, the cleaning machine 231 also has the function to remove water from the shell 11 and the door 12 after wet cleaning. Or, at least one water removal machine (not shown in the figure) is arranged between the cleaning machine 231 and the vacuum drier 232 to remove water from the shell 11 and the door 12 after wet cleaning in advance, so as to shorten the subsequent drying time.

Each of the vacuum driers 232 is used to house the shell 11 and the door 12 after wet cleaning or water removal. Alternatively, the shell 11 and the door 12 after wet cleaning or water removal can be respectively placed in different vacuum driers 232 to remove the water molecules on the surfaces of the shell 11 and door 12 after wet cleaning.

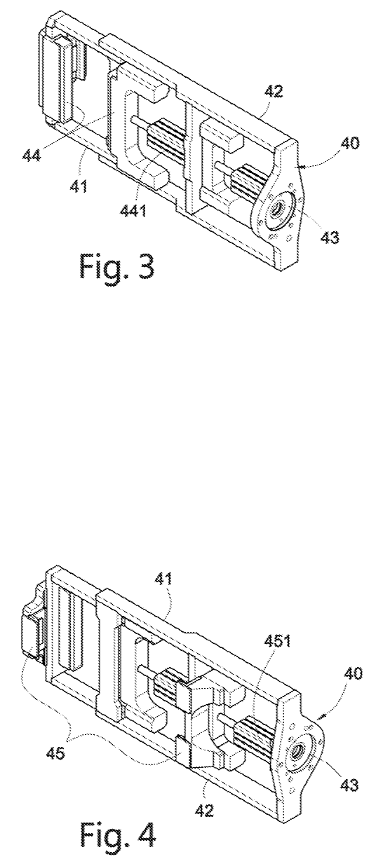

Reference is now made to FIGS. 3 and 4 in combination. FIG. 3 shows the perspective view of the gripper 40 shown in FIG. 2 from the first angle. As shown, the gripper 40 can be formed as a frame-like structure with two end faces 41 and 42. These end faces 41 and 42 may be implemented in a manner that they are parallel and corresponding to each other. Additionally, one side of the gripper 40 includes a connecting seat 43 for locking connection to the automatic machine 30. On one of the end faces (e.g., end face 41), a first clamper 44 is provided to clamp the flange 15 of the shell 11. As further shown in FIG. 4, the other end face 42 of the gripper 40 is equipped with a second clamper 45 for clamping the opposing edges of the door 12. The first clamper 44 and second clamper 45 are respectively driven by drivers 441 and 451, enabling them to adjust their clamping apertures.

As depicted in FIG. 5, the gripper 40 can execute a 180-degree flipping action, allowing the first clamper 44 and second clamper 45 mounted on the end faces 41 and 42 to simultaneously clamp the flange 15 of the shell 11 and the opposing edges 121 and 122 of the door 12.

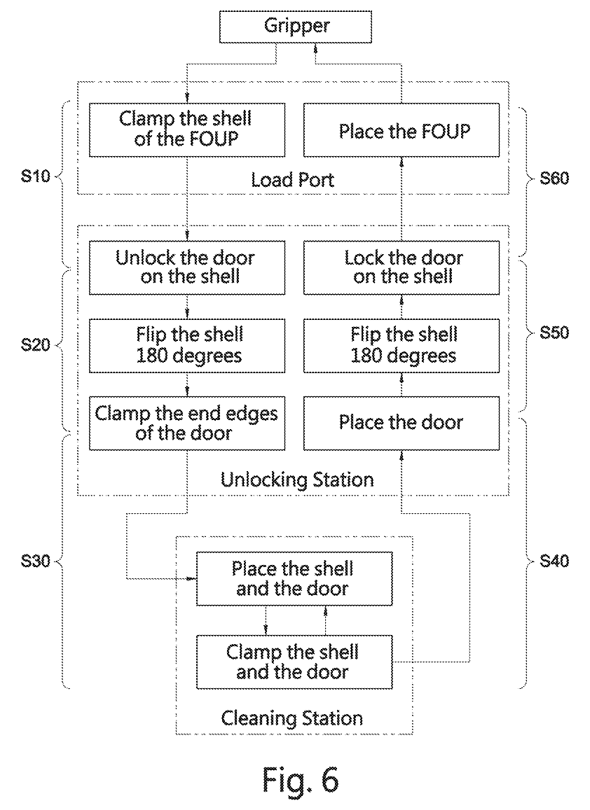

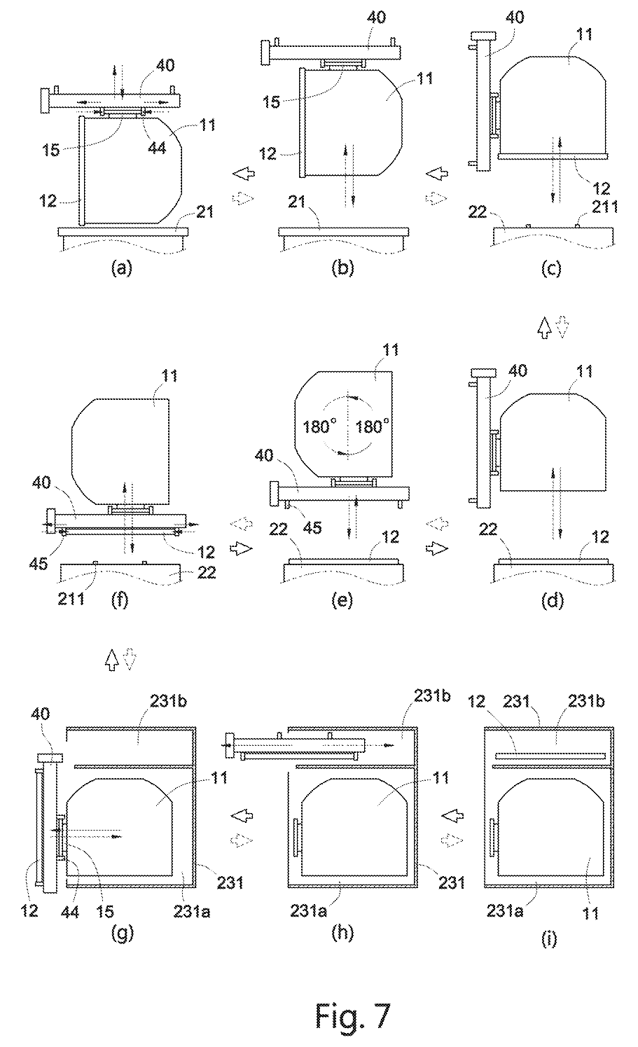

Further reference is made to FIG. 6 and FIG. 7. Specifically, FIG. 6 discloses that the gripper 40 can execute a one-time transportation path (indicated by the arrowed line segments in FIG. 3) in the cleaning area station 20. The transportation path comprises the following steps S10 to S60. FIG. 7 supplements the operational actions of the gripper 40 during the execution of steps S10 to S60.

Further, please refer to FIG. 7(a) to (i) for the subsequent steps S10 to S30 described below. In the illustrations, dashed solid arrows denote the operational movements of the gripper 40, and the dashed hollow arrows indicate the sequential order from (a) to (i).

Step S10: Clamp the FOUP to be cleaned and unlock the door on the shell.

In this step, the automatic machine 30 drives the gripper 40 to the load port 21 to clamp the FOUP 10 to be cleaned. At this point, the door 12 on the shell 11 of the FOUP 10 remains locked, and the gripper 40 secures the FOUP 10 by clamping the flange 15 on the shell 11, facilitating the transportation of the entire FOUP 10 to the unlocking station 22 to unlock the door 12 on the shell 11.

As shown in FIG. 7(a), the gripper 40 moves to the load port 21 and uses the first clamper 44 to clamp the flange 15 on the shell 11. As illustrated in FIG. 7(b), the gripper 40 lifts the shell 11 away from the load port 21 via the first clamper 44, with both the shell 11 and the door 12 on it being lifted simultaneously. As depicted in FIG. 7(c), the gripper 40 is driven by the multi-axis automatic machine 30 to move to the unlocking station 22, tilting the door 12 downward and placing it onto the platform of the unlocking station 22. The platform of the unlocking station 22 is provided with keys of the unlocking mechanism key 211, which are automatically inserted into the keyhole of the door 12 during the downward placement, thereby unlocking the door 12.

Step S20: Flip the shell and clamp the door.

In this step, the gripper 40 lifts the shell 11 with unlocked door 12 away from the platform of the unlocking station 22 and executes a 180-degree flipping action, enabling the second clamper 45 of the gripper 40 to clamp the opposite end edges 121 and 122 of the door 12.

Further, as shown in FIG. 7(d), the gripper 40 lifts the shell 11 (with the unlocked door 12) away from the platform of the unlocking station 22 and leaves the door 12 on the platform, thereby separating the shell 11 and the door 12. Subsequently, as illustrated in FIG. 7(e), following the lifting action of the shell 11 from the platform of the unlocking station 22, the gripper 40 continues to rotate the clamped shell 11 by 180 degrees, so that the second clamper 45 of the gripper 40 faces downward to correspond to the door 12 on the unlocking station 22. The gripper 40 then moves downward, and the second clamper 45 clamps the opposite end edges 121 and 122 of the door 12, so that the two end faces of the gripper 40 can respectively clamp the shell 11 and the door 12.

Step S30: Transport the shell and door to the cleaning station for placement.

In this step, the gripper 40, already holding the shell 11 and the door 12, transports the shell 11 and the door 12 away from the unlocking station 22 to the cleaning station 23 for sequential placement of the shell 11 and the door 12. As shown in FIG. 2, there are a plurality of cleaning stations 23 with cleaning machines 231 and vacuum dryers 232. The gripper 40 can first place the shell 11 and the door 12 into the same or different cleaning machines 231. After the cleaning is completed, the gripper 40 retrieves the shell 11 and the door 12 from the cleaning machine 231 and transports them to a vacuum dryer 232 for placement, and so on. This allows the gripper 40 to sequentially place and retrieve the shell 11 and the door 12 across multiple cleaning stations 23. In this way, the required cleaning process for the shell 11 and the door 12 can be completed.

Further, as shown in FIG. 7(f), the gripper 40 transports the shell 11 and the door 12 away from the unlocking station 22 and carries them to the cleaning machines 231 within multiple cleaning stations 23 [as shown in FIG. 7(g)]. As an example, the cleaning machine 231 is configured with a shell cleaning chamber 231a and a door cleaning chamber 231b. The gripper 40 can firstly place the shell 11 into the shell cleaning chamber 231a [as shown in FIG. 7 (g)], and then place the door 12 into the door cleaning chamber 231b [as shown in FIG. 7 (h)]. Thus, the shell 11 and the door 12 can be held in the cleaning machine 231 for cleaning [as shown in FIG. 7 (i)].

Additionally, in the subsequent steps S40 to S60, refer back to FIGS. 7(i) to (a) in reverse order. The solid filled arrows indicate the movements of the gripper 40, while the solid hollow arrows denote the sequence from (i) to (a).

Step S40: Transport the cleaned shell and door to the unlocking station.

In this step, the gripper 40 simultaneously picks up the shell 11 and the door 12 that have completed the cleaning process and leaves the cleaning station 23. Then, it simultaneously transports the shell 11 and the door 12 to the unlocking station 22 for placement.

Further, please refer back from FIGS. 7(i) to 7(f) in sequence. The cleaned shell 11 and door 12 inside the cleaning machine 231 [as shown in FIG. 7 (i)] can be successively clamped by the gripper 40 and leave the shell cleaning chamber 231a and the door cleaning chamber 231b successively [as shown in (h) to (g) of FIG. 7]. The gripper 40 then transports the shell 11 and the door 12 to the unlocking station 22 [as shown in FIG. 7 (f)] to place the door 12 on the platform of the unlocking station 22.

Step S50: Flip the shell and lock the FOUP.

In this step, the door 12 is retained in the unlocking station 22. The gripper 40 moves the shell 11 upward, then flips it for 180 degrees, and then moves it downward onto the door 12. The door 12 is locked onto the shell 11, and the assembly of the FOUP 10 is completed.

Further, once the door 12 is placed on the platform of the unlocking station 22, the key 211 on the unlocking station 22 can be inserted into the key hole of the door 12. This allows the door 12 to remain on the platform of the unlocking station 22 as the gripper 40 drives the shell 11 upward. The gripper 40, which is still holding the shell 11, flips for 180 degrees during the upward movement [as shown in FIG. 7 (e)]. This makes the opening of the shell 11 face downward and correspond to the door 12 on the platform of the unlocking station 22 [as shown in FIG. 7 (d)]. The gripper 40 then moves the shell 11 downward to lock the door 12 on the platform of the unlocking station 22. In this way, the shell 11 and the door 12 can be locked together again to form the FOUP 10.

Step S60: Transport the FOUP to the load port.

In this step, the gripper 40 grips the flange 15 of the shell 11 from the unlocking station, and then transports the FOUP 10 to the load port 21 for placement.

Further, as shown in FIG. 7 (c), the gripper 40 grips the flange 15 of the shell 11 from the unlocking station, and then moves the cleaned and locked FOUP 10 away from the unlocking station 22. Then, as shown in FIG. 7 (b), the gripper 40 immediately moves the cleaned and locked FOUP 10 to the load port 21. After placing the FOUP 10 on the load port 21, the gripper 40 releases the FOUP 10 to complete the operation of the the gripper 40 along a one-time transportation path.

Specifically, the cleaning machine 231 shown in FIG. 7 (g) to (i) is just one embodiment of the multiple cleaning stations 23. It is to be understood that any variations such as a single cleaning chamber dedicated to cleaning the shell 11 or a multi-slot cleaning chamber dedicated to cleaning the door 12 planned inside the cleaning machine 231 shall all be deemed as simple replacement to the technique considered by the present invention.

In addition, according to the above description of clamping and placing the shell 11 and the door 12 inside the cleaning machine 231, it is to be noted that the method also applies to placing and clamping the shell 11 and the door 12 inside the vacuum drier 232.

Moreover, in the above, since the gripper 40 can clamp and move the shell 11 and the door 12 at one time, the gripper 40 only needs to perform a single round-trip movement between the unlocking station 22 and the cleaning station 23 to complete the work of taking and placing the shell 11 and the door 12. In this way, when the gripper 40 needs to carry the heavier shell 11 or the entire FOUP 10, it can still clamp on the position of the flange 15 on the shell 11. This complies with the standard for operating FOUPs 10 and can maintain the durability of the FOUPs 10.

Although the invention has been explained in relation to its preferred embodiment, it is to be understood that many other possible modifications and variations can be made without departing from the spirit and scope of the invention as hereinafter claimed.

1. A FOUP carrying method for transporting the FOUP for cleaning, wherein the FOUP before cleaning comprises a shell and a door locked onto the shell, and the weight of the FOUP and the shell is relatively heavier than the door; the carrying method comprises constructing a one-time transportation path for a gripper to grip and disassemble the FOUP between a load port, an unlocking station, and a cleaning station, wherein the gripper has a first clamper and a second clamper respectively provided on its two end faces, and the one-time transportation path of the gripper sequentially includes:
(1) grasping the shell via the first clamper from the load port to transport the FOUP awaiting cleaning to the unlocking station for unlocking the door on the shell, and lifting the shell while leaving the unlocked door at the unlocking station;
(2) grasping the unlocked door via the second clamper from the unlocking station, thereby simultaneously transporting the shell and the door to the cleaning station for respective placement;
(3) grasping the shell via the first clamper from the cleaning station and grasping the door via the second clamper from the cleaning station, thereby simultaneously transporting the shell and the door to the unlocking station for locking and presenting the cleaned FOUP; and
(4) grasping the shell via the first clamper from the unlocking station to transport the cleaned FOUP to the load port for placement;
wherein, one side of the shell forms a flange, and when the gripper transports the FOUP and the shell, the flange provides clamping points for the first clamper, and when the gripper transports the door, the second clamper clamps the door; the gripper undergoes reciprocating swing at a specific angle to enable the first clamper to clamp the flange and the second clamper to clamp the door.

2. The FOUP carrying method defined in claim 1, wherein the specific angle is 180 degrees.

3. The FOUP carrying method defined in claim 1, wherein the two end faces of the gripper are parallel and corresponding to each other.

4. The FOUP carrying method defined in claim 1, wherein the two lateral edges of the door provide clamping points for the second clamper.

5. A FOUP carrying device for transporting the FOUP for cleaning, wherein the FOUP before cleaning comprises a shell and a door locked onto the shell, and the weight of the FOUP and the shell is relatively heavier than the door; the carrying device comprises:
an automatic machine, connected to a gripper and located in a cleaning area station, wherein, around the automatic machine in the cleaning area station, at least one load port, at least one unlocking station, and a plurality of cleaning stations are disposed;
a first clamper, provided on one end face of the gripper, used to clamp and release the flange on the shell at the load port, the unlocking station, and the cleaning station; and
a second clamper, provided on the other end face of the gripper, used to clamp and release the door at the load port, the unlocking station, and the cleaning station;
wherein, the gripper undergoes reciprocating swing at a specific angle to enable the first clamper to clamp and release the flange, and the second clamper to clamp and release the door.

6. The FOUP carrying device defined in claim 5, wherein the specific angle is 180 degrees.

7. The FOUP carrying device defined in claim 5, wherein the two end faces of the gripper are parallel and corresponding to each other.

8. The FOUP carrying device defined in claim 5, wherein the two lateral edges of the door provide clamping points for the second clamper.
